(19) United States
(12) Patent Application Publication
(10) Pub. No.: US 2026/0168133 A1
(43) Pub. Date: Jun. 18, 2026

(54) METHOD FOR MANUFACTURING POLYCRYSTALLINE SILICON CARBIDE SUITABLE FOR MANUFACTURING SUBSTRATES FOR INTEGRATED CIRCUITS, AND SILICON CARBIDE OBTAINED IN THIS WAY

(71) Applicant: MERSEN FRANCE GENNEVILLIERS SAS, GENNEVILLIERS (FR)

(72) Inventors: Alexandre POTIER, Verneuil Sur Seine (FR); Marc FERRATO, Horgues (FR); Pablo LEFEVRE, Colombes (FR)

(73) Assignee: MERSEN FRANCE GENNEVILLIERS SAS, GENNEVILLIERS (FR)

(21) Appl. No.: 18/852,260

(22) PCT Filed: Mar. 28, 2023
(86) PCT No.: PCT/IB2023/053082

§ 371 Date: Sep. 27, 2024

(30) Foreign Application Priority Data
Mar. 30, 2022 (FR) FR2202858

(51) Int. Cl. C30B 29/36; C30B 28/14

(52) U.S. Cl. CPC C30B 29/36; C30B 28/14

(57) ABSTRACT

The invention relates to a method for manufacturing a plate made of polycrystalline SiC, doped by chemical vapour deposition on a graphite surface, wherein a gas mixture is introduced into a heated chamber so as to create a gas phase comprising: —at least one gaseous precursor of silicon and/or carbon; —at least one dopant gas comprising at least one nitrogen atom; and —a carrier gas, the gas mixture decomposing on the graphite surface to form a layer of polycrystalline SiC, and the method being characterised in that the temperature in the reactor is between 1450 K and 1650 K and the total partial pressure of the gaseous precursors is less than 350 mbar. The plate is characterised in that: (i) the texture coefficient C₄₂₂ thereof is less than 30%, and (ii.a) the texture coefficient C₂₂₀ thereof is greater than 60%, or (ii.b) the sum of the texture coefficients C₁₁₁+C₂₂₂+C₅₁₁ is greater than 70%.

### CROSS-REFERENCE TO RELATED APPLICATIONS

The present application is a National Stage Application of PCT International Application No. PCT/IB2023/053082 (filed on Mar. 28, 2023), under 35 U.S.C. § 371, which claims priority to French Patent Application No. 2202858 (filed on Mar. 30, 2022), which are each hereby incorporated by reference in their complete respective entireties.

### TECHNICAL FIELD

The invention relates to the field of materials science, and more particularly to the field of materials which can be used for the manufacture of substrates for integrated circuits, and to processes for producing these materials. It concerns more specifically polycrystalline silicon carbide. This material, like all materials for microelectronic substrates, is implemented in the form of thin slices (for which the skilled person often uses, in French, the English term “wafer”), which are typically circular in shape. SiC is particularly suitable for the fabrication of substrates for use in power electronic components. SiC wafers must meet very strict specifications regarding their flatness, the homogeneity of their properties and the absence of defects.

The present invention presents a new type of polycrystalline SiC wafers usable for the manufacture of integrated circuit substrates; these wafers have particular crystallographic characteristics.

Since integrated circuits are generally deposited on surfaces of a single-crystal semiconductor, in the case of a polycrystalline silicon carbide wafer, the electronically active surface (i.e. the surface on which the integrated circuits are deposited) must be specially prepared by transferring a layer of single-crystal SiC. This method of preparation by transfer of a monocrystalline SiC layer is not part of the present invention.

The present invention also relates to a new method for manufacturing such a polycrystalline silicon carbide wafer capable of receiving, in a subsequent manufacturing step, the transfer of a layer of monocrystalline SiC.

### BACKGROUND

Since the beginning of microelectronics, the vast majority of microelectronic circuits have been manufactured on a monocrystalline silicon substrate. For some specific applications, semiconductor silicon is not the ideal substrate, but it is used for lack of anything better.

Silicon carbide (abbreviated SiC), on the other hand, is a remarkable semiconductor material. It has a wide band gap, high breakdown field, high charge carrier mobility at saturation and high thermal conductivity. This combination of exceptional physical properties gives it excellent voltage resistance, as well as the passage of very high current densities, even at high temperatures. The article “Power components in SiC—Technology” by D. Tournier, published in 2007 as part D-3120 in the Techniques de l'ingénieur collection, provides an introduction to the subject.

SiC is therefore a material perfectly suited for the manufacture of power components necessary for the efficient conversion of electrical energy in applications such as electrical power distribution, renewable energies, electric vehicles. The use of SiC makes it possible to advantageously replace silicon-based transistors such as IGBTs with power components such as MOSFET transistors with voltage resistance of the order of kilovolts and much lower energy losses during switching. In these power components, voltage resistance and temperature resistance can become limiting factors when designing electronic components and the electronic boards on which these components are installed. Recent development of electric vehicles would benefit greatly from the use of such SiC power components to improve energy efficiency when converting direct current from batteries into usable alternating current by the motor. The cost and availability of these components nevertheless remain obstacles to the adoption of this technology, and for this reason silicon is still widely used as a substrate in specific applications for which SiC would present technical advantages.

According to the state of the art, silicon carbide substrates intended to receive the deposition of microelectronic circuits are presented as wafers which are generally circular in shape. They are manufactured industrially using the PVT (Physical Vapor Transfer) process, which consists of sublimating a SiC powder at high temperature (>2200° C.) and condensing the vapors on a seed to obtain an ingot or “ball” of monocrystalline SiC. From this single-crystal ingot, single-crystal SiC substrates (wafers) are then sliced. A layer of crystalline SiC is deposited by epitaxy on one of the faces of this substrate, in order to obtain a crystal with as few defects as possible. After epitaxy, these wafers will be ready to accommodate the manufacture of electronic components.

The improvement of the PVT industrial process over the last 30 years has significantly reduced the density of the main crystalline defects in these substrates, such as dislocations and micro-pipes, which had a strong impact on the reliability of SiC components. In addition, it has made it possible to increase the size of the substrates (wafers) up to a diameter of 150 mm as standard, evolving very soon towards 200 mm. Despite industrial efforts, the PVT process remains complex to master, not very productive and consuming a significant amount of energy because it requires maintaining an oven at a very high temperature for around a hundred hours.

Furthermore, for power components, the lowest possible resistance Ron in passing mode is a determining criterion for improving the energy efficiency of the system by limiting heating by the Joule effect during current flow. In these applications, the monocrystalline SiC is doped both to enable the fabrication of the P/N junctions of the component and to reduce its resistivity at the drain contact. The addition of nitrogen allows the substrate to be doped during crystal growth. As standard, “n” doped wafers have a resistivity of the order of 20 mOhm·cm. It becomes very difficult to reduce the resistivity below this threshold without degrading the quality of the crystal, because too much doping creates stresses that promote additional dislocations in the crystal.

A new technology currently under development would combine the use of a low-cost SiC substrate (wafer) with improved electrical performance and a thin layer of high-quality monocrystalline SiC in which the microelectronic component would be manufactured.

The monocrystalline SiC layer is attached to the substrate by a molecular bonding process as described in WO 01/18873 (Commissariat à l'Energie Atomique), also making it possible to guarantee a minimum contact resistance between the substrate and the attached monocrystalline layer. Document EP 3 018 696 A1 describes an embodiment of such a method, which results in a layer of monocrystalline SiC applied to a polycrystalline SiC substrate (herein referred to as “P-SiC” or “P-SiC Wafer”).

These P-SiC substrates must meet strict requirements for electrical resistance, thermal conductivity and flatness. Today, there are prototype products called “Dummy wafers” on the market, sold by companies such as Ferrotec. These wafers, with a diameter of 150 mm and a thickness of 750 μm as standard, are used to balance a full load of monocrystalline SiC wafers in certain processes to improve their uniformity.

According to the state of the art, P-SiC wafers are obtained by depositing polycrystalline SiC by CVD on a cylindrical graphite substrate. After machining away the SiC layer deposited around the cylinder to reach the graphite, two SiC discs can be separated from the two faces of the cylinder by air oxidation of the graphite. This is described in patent applications JP 1994 340994 and JP 1997 296361.

However, it quickly became apparent that the disks (wafers) thus obtained presented a deformation (Bow and Warp) unacceptable for the intended application. The Bow and Warp parameters represent the flatness of a wafer intended for the semiconductor industry and are known to those skilled in the art of semiconductor substrates for microelectronics (we only use the English words for these parameters, which we write here with a capital letter); they will be described in more detail below and can be measured according to the SEMI MF1390 standard. The processes described in the two Japanese documents cited above find a solution to the problem, thanks to the repetition of several deposition steps of low thicknesses of less than 100 μm. Indeed, for a sufficiently thick deposit, the increase in the diameter of the grains generates an internal compressive stress. The conical-shaped grains repel each other as they grow. This physical mechanism is demonstrated by P. Chaudhari in the publication “Grain growth and Stress relief in thin films”, published in Journal of Vacuum Science and Technology 9, 520 (1972), which is a basic document for any specialist in the deposition of layers from a vapor phase. The process described in JP 1994 340994 and JP 1997 296361 makes it possible to obtain thick layers of P-SiC of several hundred microns while limiting the increase in internal compression stresses and therefore makes it possible to limit their deformations once detached from the graphite.

Japanese patent JP 3648 112 B2 describes a similar process that alternates the deposition of layers with tensile and compressive stresses, in order to cancel the stress moment integrated over the entire thickness of the deposit. This mechanical moment is indeed at the origin of the deformation observed when the P-SiC disk is removed from its graphite substrate.

It is however important to note that the processes as described above are not favorable to achieve low resistivity and good thermal conductivity through the thickness of the wafer because of the multiple interfaces separating the layers in its thickness. Finding a single-layer solution to the problem would be more favorable.

U.S. Pat. No. 10,934,634 B2 describes obtaining a P-SiC wafer with excellent flatness from a SiC monolayer deposited by CVD on a graphite substrate. A sufficiently thick deposit, typically 2 mm, has an upper portion where the variation in grain diameter is stabilized. Since the compressive stress no longer changes in this portion (as demonstrated in the cited publication by Chaudhari), it is then possible to extract by machining a slice with a thickness of 350 μm which presents a quasi-zero stress gradient like the grain sizes in the thickness and therefore to integrate a quasi-zero mechanical moment over the thickness. The expected effect is a very low deformation of the wafer. However, the cost and energy expended by such a process is probably unfavorable, since about 1.65 mm of the 2 mm CVD-deposited layer must be removed by grinding and polishing to obtain the wafer at the desired thickness of 350 μm with the desired flatness.

To reduce the manufacturing costs of a doped P-SiC wafer, it would be optimal to grow by CVD at high speed a P-SiC layer of thickness as close as possible to the final thickness with a grain size very quickly stabilized after the start of the layer growth, to avoid any unnecessary extra thickness that would become necessary to reduce or eliminate the grain size gradient.

At the Transducers & Eurosensors 2007 conference, X. A. Fu et al. published a paper entitled “Nitrogen doped polycrystalline 3C-SiC films deposited by LPCVD for MEMS applications.”

In this paper, the authors study the deposition of SiC for dopant gas levels (NH₃) varying from 2% to 12% in molar fraction of the silicon precursor (Dichlorosilane). To obtain a resistivity below 20 mohm·cm under these conditions, the dopant rate must exceed 5%. A higher dopant rate leads to an increase in the residual stress without increasing the stress gradient. In this study, the deposition is carried out at low temperature 900° C. and low pressure favoring a crystalline growth exclusively along the (111) axis, but with an extremely slow deposition rate of 0.6 μm/h. Significant doping does not appear to modify the crystalline orientation of the deposited thin layer under these conditions, measured by X-ray diffraction (XRD) analysis.

In the publication of H. K. E. Latha et al published in 2014 in the journal Mater. Res. Express 1 015902, the effects of high doping of 3C-SiC obtained by CVD using methyltrichlorosilane (MTCS) as silicon and carbon precursor, and NH₃ as doping agent are studied. The deposition conditions are 1040° C. at low pressure. The growth rate of the deposit reaches approximately 5 μm/h, much higher than the previous case, but still very insufficient to produce high thicknesses (several hundred microns) in an economically viable manner. An influence of the doping level on the crystal orientation and grain size is observed under these conditions. A high level of doping is accompanied by a coarsening of the grain size and their crystal orientation axis is modified according to X-ray diffraction (XRD) analysis. For certain CVD conditions, particularly at higher temperatures, here 1040° C. instead of 900° C. as described in the publication of Fu et al. cited above, it seems that a high level of doping can have a very significant influence on the crystalline orientations of SiC deposits by CVD. Thus the textures and grain sizes obtained can modify the stress distribution in these deposits.

Patent application WO 2021/060515 (Tokai Carbon) proposes a process for obtaining a P-SiC substrate with a thickness of between 500 μm and 6 mm, at a high deposition temperature close to 1500° C. The deposition time is between 5 h and 15 h, i.e. deposition rates above 100 μm/h, particularly suitable for industrial production. Doping of P-SiC is achieved by adding dinitrogen into the mixture. To obtain a sufficiently flat substrate, the patent proposes a process which varies the concentration of SiC precursor during deposition, in order to reduce the grain size gradient which is too pronounced in the deposit. This process is proposed for nitrogen mass concentrations between 200 ppm (2.8×10¹⁹ atm/cm³) and 1000 ppm (1.38×10²⁰ atm/cm³). Beyond 1000 ppm, it is noted that excessive nitrogen concentration in P-SiC would generate significant defects in the crystals and unwanted substrate deformation. Thus, this state-of-the-art document also shows that a high concentration of nitrogen dopant in the P-SiC material is potentially a limiting factor for to obtain good flatness, but it is desirable to obtain low electrical resistivity.

These conflicting trends must be taken into account when seeking to fabricate a raw P-SiC substrate by CVD with low resistivity (e.g. <10 mOhm·cm) and sufficient flatness to be able to grind a P-SiC wafer by removing as little material thickness as possible. Regarding the flatness of the raw substrate obtained by CVD, it must be kept in mind that the removal of material by grinding of a surface as hard as that of SiC is a long and expensive process, and in addition, any thickness of material removed by grinding corresponds to material that is lost. Indeed, the manufacturing cost of the P-SiC wafer must reach a sufficiently low level to be able to serve as a substrate combined with a thin layer of polycrystalline SiC in power electronics applications.

According to the state of the industrial technique, the nominal thickness of the finished P-SiC wafer is 350 μm for a nominal diameter of 150 mm. A thicker raw product (raw blank) is made using a CVD deposition process on a graphite substrate. For economic reasons, once detached from the graphite, the P-SiC blank must not exceed a thickness of 1 mm; typically 750 μm and preferably 600 μm are targeted, in order to obtain a reasonable CVD deposition time and to reduce the thickness to be removed by grinding and polishing, to respectively a maximum of 650 μm, typically 400 μm, preferably 250 μm.

The warp of a 350 μm thick wafer with a six-inch diameter must be less than 50 μm after grinding and polishing to comply with microelectronics standards. To achieve this objective, it is first necessary to prepare an intermediate blank by grinding from the raw blank detached from the graphite, which will then serve as a starting point to prepare, by fine grinding followed by polishing, the P-SiC wafer onto which a monocrystalline layer of SiC will then be transferred. The difference between the initial thickness of the raw blank and the deformation measured on said raw blank must not be less than the thickness of the intermediate blank. This means that the volume of the ground intermediate (cylindrical) blank must be included in the volume of the raw blank (see FIG. 1).

In the present invention, the inventors sought to optimize the manufacture of a raw SiC substrate having a high N dopant rate typically greater than 5×10¹⁹ atoms/cm³, preferably greater than 10²⁰ atoms/cm³, to achieve typically a material resistivity of less than 15 mOhm·cm and preferably less than 10 mOhm·cm. The thermal conductivity of the material should typically be greater than 200 W/mK, but a value greater than 250 W/m/K is preferred, despite a high N dopant content which can affect the thermal conductivity by generating additional crystal defects harmful to phonon propagation. We also look for a substrate that has excellent surface homogeneity of its grain size, and preferably a fine grain.

### SUMMARY

It results from the work carried out by the inventors of the present application that a solid plate of polycrystalline SiC (denoted here “P-SiC”) can be obtained by chemical vapor deposition (CVD) operating in a temperature range from approximately 1300 K to approximately 1800 K on a substrate comprising a graphite surface. In this method, which forms the first object of the present invention, a mixture of gases is introduced into a heated enclosure so as to create a gas phase comprising at least one gaseous precursor of silicon and/or carbon, at least one dopant gas comprising at least one nitrogen atom, and a carrier gas, said mixture of gases decomposing on the surface of said graphite substrate to form a layer of polycrystalline SiC on said graphite surface of said substrate, and said method being characterized in that the temperature in the reactor is between 1450 K and 1650 K and the total partial pressure of said gaseous precursors is less than 350 mbar, and preferably less than 300 mbar. This deposition is made on the graphite surface of a substrate comprising a graphite surface; said substrate may be a graphite plate. This substrate, and more particularly this graphite plate, is advantageously circular, so as to allow the direct production of a circular SiC disk.

According to an advantageous embodiment, said gas phase comprises trichloromethylsilane as a precursor of silicon and carbon, and preferably does not comprise other precursors of silicon and/or carbon. Said dopant gas is advantageously selected from the group formed by: NH₃, N₂H₄, N₂, H₂NCH₃.

This process deposits a layer of polycrystalline silicon carbide (P-SiC) which can then be separated from the graphite surface on which it was formed; this produces a P-SiC disc whose thickness can be reduced by grinding and then polishing both sides.

Thus, a polycrystalline SiC plate can be produced, which represents another object of the present invention. This plate can be a raw blank, which can then undergo rectification steps to become an intermediate blank for the manufacture of a polycrystalline SiC substrate capable of receiving a transfer of a layer of monocrystalline SiC to form a wafer usable for the manufacture of a substrate for the deposition of integrated circuits. Said plate, said raw blank and said intermediate blank represent other objects of the present invention, as will be explained later. They advantageously present a particular microstructure and crystallographic texture, as will be explained below.

Said polycrystalline SiC plate has a particular crystallographic texture, which can be obtained for particular doping and conductivity characteristics. Thus, a second object of the invention is a polycrystalline SiC plate, characterized in that: (i) its texture coefficient C₄₂₂ is less than 30%, and (ii.a) its texture coefficient C₂₂₀ is greater than 60% and preferably greater than 80%, or (ii.b) the sum of the texture coefficients Cin+C₂₂₂+C₅₁₁ is greater than 70%; and preferably greater than 80%. Advantageously, its texture coefficient C₄₂₂ is less than 20%, preferably less than 15%, and preferably less than 10%.

This polycrystalline SiC plate according to the invention is advantageously doped, preferably with nitrogen. Another example of a doped polycrystalline SiC plate according to the invention is a phosphorus-doped plate.

Advantageously, the electrical resistivity of this polycrystalline SiC plate is less than 20 mOhm·cm, preferably less than 15 mOhm·cm, and even more preferably less than 10 mOhm·cm, and/or its nitrogen content is greater than 5×10¹⁹ atoms/cm³, preferably greater than 1×10²⁰ atoms/cm³, and even more preferably greater than 1.5×10²⁰ atoms/cm³.

Typically, in the field of microelectronic substrates, the doping rate (e.g. nitrogen rate) can be determined by secondary ion mass spectrometry (SIMS).

A particularly preferred embodiment of this second object of the invention is a polycrystalline SiC plate, doped with nitrogen with a nitrogen content, measured by secondary ion mass spectroscopy, greater than 5×10¹⁹ atoms/cm³, said plate having an electrical resistivity of less than 15 mOhm·cm and a preferential crystalline orientation, said plate being characterized in that: (i) its texture coefficient C₄₂₂ is less than 20%, and (ii.a) its texture coefficient C₂₂₀ is greater than 80%, or (ii.b) the sum of the texture coefficients C₁₁₁+C₂₂₂+C₅₁₁ is greater than 80%.

Said polycrystalline SiC plate typically has the shape of a circular disk. It is characterized by good flatness, and advantageously has either a diameter between 140 mm and 165 mm or a diameter between 185 mm and 210 mm; these two diameter ranges include the sizes currently customary in the semiconductor industry, namely 6 inches and 8 inches.

Said polycrystalline SiC plate may be a raw blank resulting from a vapor deposition process. It can also be an intermediate blank for the manufacture of a wafer obtained by grinding such a raw blank. In one embodiment, the polycrystalline SiC plate according to the invention has a thickness of less than 550 μm, preferably less than 500 μm, more preferably less than 450 μm, and even more preferably between 355 μm and 420 μm; this embodiment is particularly suitable for plates with a diameter of between 140 mm and 165 mm. In another embodiment, the polycrystalline SiC plate according to the invention has a thickness of less than 850 μm, preferably less than 800 μm, more preferably less than 750 μm, and even more preferably between 510 μm and 650 μm; this embodiment is particularly suitable for plates with a diameter of between 185 mm and 210 mm.

In an other embodiment, the polycrystalline SiC plate according to the invention has a diameter of between 140 mm and 165 mm, a thickness of between 350 μm and 450 μm and a deformation characterized by a Warp of less than 50 μm, preferably less than 40 μm and even more preferably less than 30 μm. Its thickness is preferably between 350 μm and 400 μm. For example, said plate may have a thickness of between 350 μm and 400 μm and a Warp of less than 40 μm (and preferably less than 30 μm), or its thickness may be between 400 μm and 450 μm and its Warp may then be less than 50 μm (and preferably less than 40 μm).

In yet another embodiment, the polycrystalline SiC plate according to the invention has a diameter of between 185 mm and 210 mm, a thickness of between 500 μm and 650 μm and a deformation characterized by a Warp of less than 70 μm, preferably less than 50 μm and even more preferably less than 40 μm. Its thickness is preferably between 500 μm and 600 μm. For example, said plate may have a thickness of between 500 μm and 600 μm and a Warp of less than 50 μm (and preferably less than 40 μm), or its thickness may be between 600 μm and 650 μm and its Warp may then be less than 70 μm (and preferably less than 50 μm).

Such plates can be manufactured by a CVD process.

### DRAWINGS

FIGS. 1 to 13 illustrate different aspects of the invention.

FIG. 1 schematically shows the measurement of the parameter called “Warp” which expresses a particular aspect of the flatness defect of a semiconductor wafer.

FIG. 2 shows an image obtained by scanning electron microscopy of backscattered electrons from a cross section of a P-SiC layer obtained by a process according to Example 1.

FIG. 3 shows an image obtained by direct mode scanning electron microscopy from a cross section of a P-SiC layer similar to Example 1.

FIG. 4 shows an image obtained by scanning electron microscopy of backscattered electrons from a cross section of a P-SiC layer obtained by a process according to Example 2.

FIG. 5 shows an image obtained by direct mode scanning electron microscopy from a cross section of a P-SiC layer similar to Example 2.

FIG. 6 shows an image obtained by scanning electron microscopy of backscattered electrons from a cross section of a P-SiC layer obtained by a process according to Example 3.

FIG. 7 shows an image obtained by direct mode scanning electron microscopy from a cross section of a P-SiC layer similar to Example 3.

FIG. 8 shows an image obtained by scanning electron microscopy of backscattered electrons from a cross section of a P-SiC layer obtained by a process according to Example 4.

FIG. 9 shows an image obtained by direct mode scanning electron microscopy from a cross section of a P-SiC layer similar to Example 4.

FIG. 10 shows an image obtained by scanning electron microscopy of backscattered electrons from a cross section of a P-SiC layer obtained by a process according to Example 5.

FIG. 11 shows an image obtained by direct mode scanning electron microscopy from a cross section of a P-SiC layer similar to Example 5.

FIG. 12 schematically and simplifiedly shows a vertical cross-section through a reactor according to the invention which makes it possible to manufacture a blank for a polycrystalline SiC substrate according to the invention.

FIG. 13 shows an image obtained by scanning electron microscopy of backscattered electron from a cross section of a P-SiC layer obtained by a process according to Example 6.

### DESCRIPTION

The person skilled in the art of semiconductor substrates for microelectronics knows the different ways to characterize the overall flatness of wafers: these different parameters are known by the terms or acronyms Bow (the distance between the surface and the plane corresponding to the best fit at the center of the unfixed wafer, see ASTM F534 “Standard Test method for Bow of Silicon Wafers” point 3.1.2), Warp (the sum of the maximum positive and negative deviations from the plane corresponding to the best fit for an unfixed wafer, see ASTM F 1390 “Standard test Method for Measuring Warp on Silicon Wafers by Automated Non-Contact Scanning”), TTV (Total Thickness Variation, i.e. the difference between the maximum and minimum thickness values for a fixed wafer, see ASTM F657 “Standard Test Method for Measuring Warp and Total Thickness Variation on Silicon Slices and Wafers by a Non-contact Scanning Method”), TIR (Total Indicated Reading, i.e. the sum of the maximum positive and negative deviations from the plane corresponding to the best fit for a fixed wafer), SRAD (Spherical Reference Measurement, expressing a radius of curvature for the sphere corresponding to the best fit); other acronyms express parameters to characterize the local flatness of wafers, in particular: LFPD (Local Focal Plane Deviation, i.e. the maximum distance between the surface of the wafer and the plane corresponding to the best fit (above or below the surface of the unfixed wafer), for a given area) and LTV (Local Thickness Variation, i.e. the difference between the maximum and minimum thickness values of the unfixed wafer, for a given area).

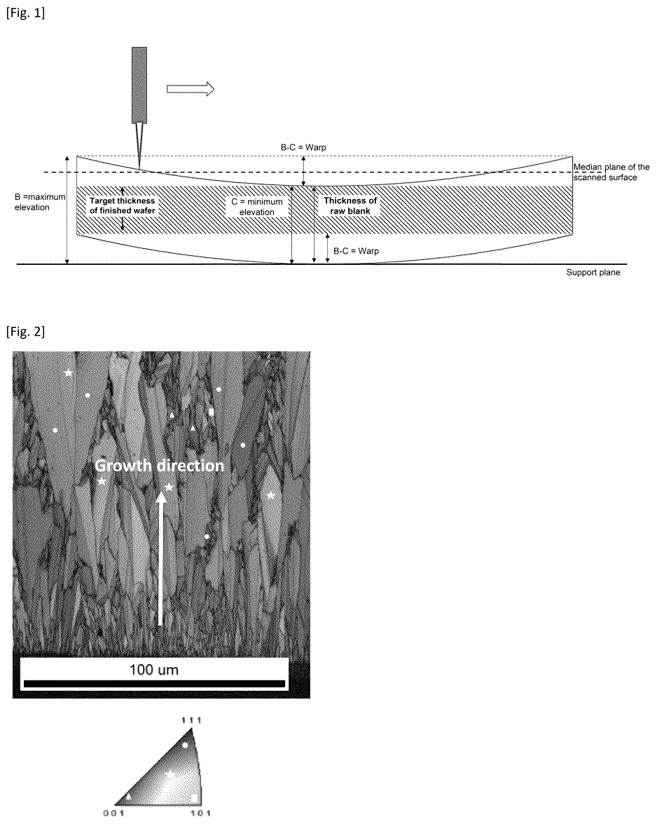

In the context of the present invention, the flatness of the wafers is characterized by the parameter commonly called “Warp.” This parameter refers to the algebraic difference of the wafer's deviations from a reference plane. FIG. 1 schematically illustrates the determination of this parameter from a surface profile by the algebraic difference of the ordinates B and C of the disk placed on a base plane.

One could also determine from the surface profile a median plane (typically by using an algorithm implementing a least-squares method) and calculate the Warp from the deviations from the median plane which gives the same result as long as the median plane is parallel to the base plane. If the median plane is not parallel to the base plane then the method of measurement relative to the base plane increases that relative to the median plane.

We now describe the method according to the invention which makes it possible to solve the problem posed.

The method according to the invention uses the chemical vapor deposition (CVD) technique, implemented in a heated enclosure. The method involves a gas mixture comprising at least one silicon precursor gas (such as a silane or a chlorosilane) and/or at least one carbon precursor gas (such as an alkane or an alkene), and/or at least one silicon and carbon precursor gas (such as methyltrichlorosilane, abbreviated MTCS), and at least one dopant gas comprising nitrogen (for example NH₃, N₂H₄, N₂). Said dopant gas can also be a precursor of carbon and/or silicon (for example an amine such as H₂NCH₃). These gases may be diluted in a carrier gas, which may be a reducing gas such as hydrogen and/or an inert gas such as argon.

By way of example, a gaseous composition for implementing the method according to the invention may comprise a carbon precursor, a silicon precursor, a dopant gas, the carrier gas.

Another example is a gaseous composition that includes a silicon and carbon precursor, a silicon precursor, a carbon precursor, a dopant gas, the carrier gas.

This gas mixture is admitted into a reactor at high temperature where the precursor gases are decomposed and react on the surface to form the 3C-SiC polytype. This material is particularly suitable for being combined with a layer of monocrystalline SiC, due to its mechanical and thermal resistance properties, its compatibility in thermal expansion and its purity. It can also be doped with nitrogen up to very high levels, typically 10²⁰ atoms/cm³ and have a resistivity much lower than 20 Ohm·cm, without degradation of the quality of the substrate which would be detrimental to the manufacture of power components. Finally, it is a material capable of subsequently resisting the high temperature processes that the wafer will have to undergo during the manufacture of the electronic component.

The temperature of the reactor during CVD deposition of SiC should be between about 1300 K and about 1800 K, and preferably between about 1350 K and about 1700 K, more preferably between about 1400 K and about 1650 K, and even more preferably between about 1450 K and about 1650 K. The total pressure in the reactor advantageously does not exceed 350 mbar, and preferably does not exceed 300 mbar.

In an advantageous embodiment of the method for manufacturing the P-SiC wafer according to the invention, the deposition is carried out by the CVD route on a graphite surface of a substrate. Very advantageously, said substrate is a substrate in fine-grained and purified isostatic graphite, this to avoid any contamination and degassing of impurities during deposition. For example, to obtain a wafer with a diameter of 150 mm, the deposition is carried out on a disc-shaped graphite cylinder, with a diameter approaching a nominal of 150 mm and a thickness greater than 2 mm to ensure sufficient flatness of the substrate. The reactor may comprise a plurality of such disks, the diameter of which may be the same or different. Both sides of the discs preferably have a flatness of <15 μm, obtained by sufficiently precise machining. The coefficient of thermal expansion of isostatic graphite is judiciously chosen to be compatible with the SiC layer during cooling after deposition. A substrate marketed by the company MERSEN under the designation “grade 2303” can be used.

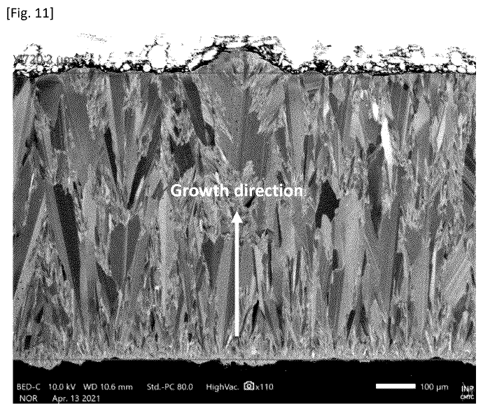

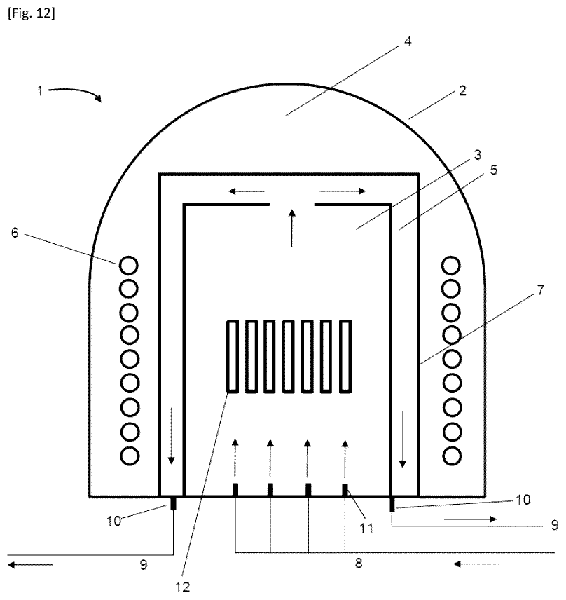

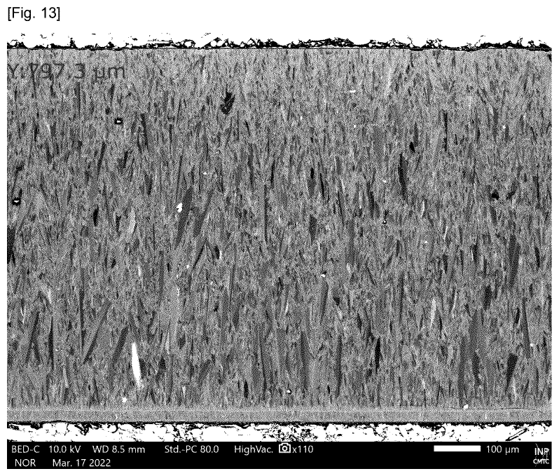

The course of a typical embodiment of the method according to the invention will now be described, and a reactor in which the method according to the invention can be carried out will first be described in relation to FIG. 12, by way of example. The process according to the invention takes place in a reactor 1 of a particular type. It comprises a reaction chamber 2, which contains a reaction space 3, a heating space 4 and a space 5 for evacuating the reaction gases. Said enclosure 2 is designed to be able to reach low pressures down to a minimum of a few tens of millibars by pumping gases to an effluent treatment device (not shown in the figure). The precursor gases are admitted into the reaction space 3 of the reactor 1 through a plurality of injectors 11 supplied by a gas line 8 called the precursor gas inlet. The reaction gases leave the reaction space 3 towards the exhaust space 5, from where they are sucked through an outlet nozzle 10 into the gas line 9 called the reaction gas outlet. The heating space 4 comprises a plurality of heating elements 6, typically solenoids. Graphite cylinders or disks 12, also called substrates here, are loaded into the enclosure 2; to simplify, FIG. 12 does not show the supports which hold said substrates 12 in the reactor 1.

The deposition chamber 2 is heated by induction of a magnetic field in a graphite susceptor 7 inside which the precursor gases (for example silanes, alkanes and/or methyl-chlorosilanes), the carrier gases (for example hydrogen and/or argon), the dopant gas (for example NH₃, amines and/or N₂) will circulate. The graphite substrates 12 are in thermal equilibrium inside the reaction space 3 heated by the susceptor 7 at a temperature generally between 1300 K and 1700 K (measured by a thermocouple), and more preferably between 1350 K and 1650 K. The gas mixture is introduced by nozzles or injectors 11 allowing a homogeneous distribution of the gas flow in the enclosure 2. In this temperature range, deposition rates can vary over quite wide ranges, from μm/h to over 100 μm/h. The total partial pressure of said gaseous precursors is advantageously less than 350 mbar, and preferably less than 300 mbar.

To achieve a minimum P-SiC deposit thickness of around 600 μm, the gas injection time can vary from a few hours to several tens or even hundreds of hours depending on the conditions chosen. The control parameters indicated above can be adjusted to obtain the product according to the invention, as will be explained in greater detail in connection with the examples. Thus, it is possible to obtain high-quality P-SiC plates at economically satisfactory conditions, allowing them to be used in electronic applications replacing monocrystalline SiC produced by the traditional PVT process.

When the deposit thickness on the surface of the graphite substrate 12 is reached, the injection of precursor gases into the furnace is stopped and the enclosure is cooled to room temperature to be discharged. The graphite discs 12 coated with a thick layer of SiC deposit are then machined, then oxidized in air typically at 900° C. to remove any graphite residue. A raw SiC disk is recovered for each face.

The deformation of the disk, a raw blank, is measured using a white light confocal sensor which scans the surface of the SiC disk which was in contact with the graphite. To perform this measurement, the face of the disc on the CVD deposit side is placed on a support. The difference between the maximum and minimum elevation of the surface scanned by the sensor relative to the support plane of the measuring tool is measured. The graphite side surface was a flat reference before being detached from the graphite. After detachment of the graphite, this surface becomes warped due to the relaxation of the stresses of the deposited layer. This warped surface can be interpolated by a median plane, by the method of least squares. If this median plane is parallel to the support plane, the deformation measure is equal to the Warp. This method of measuring deformation majorizes the measurement of the Warp in the general case.

If the deformation measurement on the raw blank is in accordance with the objective set below, it can be rectified to a thickness slightly greater than the nominal of 350 μm and to obtain a final warp of less than 50 μm for a standard 6-inch size wafer.

In fact, it is first necessary to prepare an intermediate blank by grinding from the raw blank detached from the graphite, which will then serve as a starting point to prepare, by fine grinding followed by polishing, the P-SiC wafer onto which a monocrystalline layer of SiC will then be transferred. The difference between the initial thickness of the raw blank and the deformation measured on said raw blank must not be less than the thickness of the intermediate blank. This means that the volume of the ground intermediate (cylindrical) blank must be included in the volume of the raw blank (see FIG. 1). The rectification step will also aim to remove sufficient thickness from the side of the face in contact with the graphite. This removes the initial growth zone of the crystals, which eliminates the strong stresses generated by this evolution of the deposit.

Over the temperature range 1373 K to 1673 K, the crystal growth orientation of P-SiC was studied by So and Chun in the paper “Growth and structure of chemical vapor deposited silicon carbide from methyltrichlorosilane and hydrogen in the temperature range of 1100 to 1400° C.” (Journal of Vacuum Science & Technology A 6, 5 (1988)). FIG. 4 of this document shows for this temperature zone a transition of the texture coefficient from the preferential orientation (111) at low temperature to the orientation (220) at high temperature. The texture coefficient was measured using the method described in G. B. Harris's (1952) publication “X. Quantitative measurement of preferred orientation in rolled uranium bars”, published in Philosophical Magazine Series 7, 43:336, 113-123.

The product obtained by the process according to the invention not only has excellent flatness (characterized by a low value of the Warp parameter), low electrical resistance and good thermal conductivity, but also has at its upper surface (i.e. the surface remote from the growth substrate, obtained by removal of material by polishing) a small grain size and good homogeneity of the grain size.

### EXAMPLES

Examples 1 to 6 illustrate certain aspects of the invention, but do not limit its scope.

In these examples, diffraction peaks were collected by a PANalytical X'Pert PRO MPD X-ray diffractometer using the θ-2θ method over an angle range of 10° to 135° (scale 2 θ). In this range, the ten diffraction peaks shown in Table 1 were taken into account for SiC 3C, classified according to increasing Miller indices (hkl):

TABLE 1
Diffraction peaks taken into account

| | | Theorerical intensity I [%] |
|---|---|---|
| Hkl | Position 2θ of peaks [°] | (Source ICDD) |
| 111 | [34,940°-36,345°] | 100 |
| 200 | [41,230°-41,584°] | 23 |
| 220 | [59,494°-60,452°] | 57 |
| 311 | [71,167°-72,348°] | 48 |
| 222 | [75,303°-75,749°] | 10 |
| 400 | [89,575°-90,298°] | 12 |
| 331 | [100,250°-101,537°] | 25 |
| 420 | [104,045°-104,885°] | 13 |
| 422 | [119,276°-120,418°] | 14 |
| 511 | [132,367°-134,021°] | 15 |

A texture coefficient Cₕₖₗ (for N=10 peaks) is calculated from the intensity of the peak Iₙₖₗ proportional to the area under the peak of the sample and the theoretical intensity I_{0 hkl} of a powder which can be obtained from the theoretical % published by the ICDD (International Centre for Diffraction Data).

$${C}_{hkl} = ( {I}_{hkl} / {I}_{0 hkl} ) / ( 1 / N \times \sum ( {I}_{hkl} / {I}_{0 hkl} ) ) .$$

The texture coefficient in this case ranges from 0 to 10. It can also be expressed as a %. It allows to quantify the average preferential orientation of the crystallites of the deposited layer relative to the normal to the surface of the sample.

In these examples, the carbon source and the silicon source were the same molecule, namely methyl trichlorosilane (abbreviated MTCS). The nitrogen source dopant gas was NH₃. By modifying the few key parameters of the CVD process (temperature, partial pressure of the precursor, % of dopant gas) it is possible to change the orientation of the deposited layer and its texture. This will have an impact on the gradient of internal stress of the deposit allowing to obtain a Warp on the raw blank conforming to the objective.

### Example 1: Conical Coarse Grain Texture with Preferential Orientation (422)

A 650 μm layer was deposited on a graphite substrate, operating at a temperature of 1550 K, a partial pressure of 23 mbar of MTCS and a molar fraction of NH₃ of 3%.

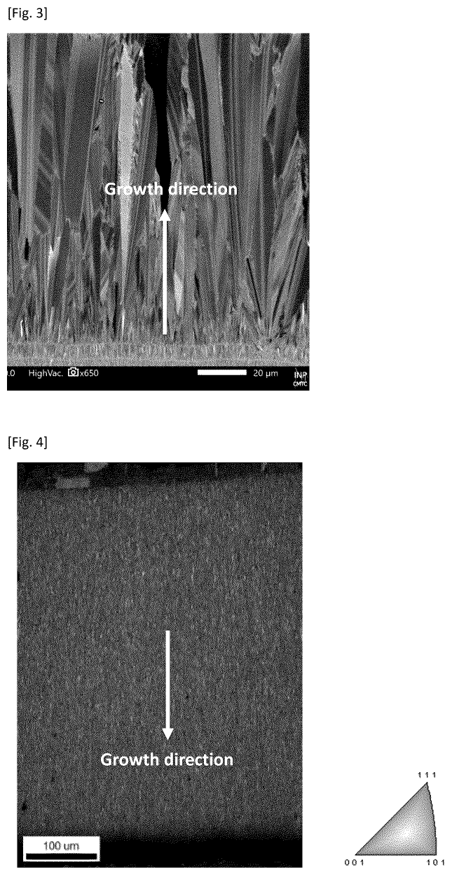

FIG. 2 shows the scanning electron microscopy image of backscattered electrons obtained from a cross section of the obtained P-SiC layer; the substrate is at the bottom and the black bar corresponds to a length of 100 μm. At the bottom is indicated the texture triangle on which are indicated for information purposes certain facets marked with four different white symbols. FIG. 3 shows a similar image obtained by direct mode scanning electron microscopy, at a higher magnification; the white bar corresponds to a length of 20 μm.

In these two micrographs, the substrate is at the bottom.

The observed orientation is a preferentially oriented texturing (422) with texture coefficients collected in Table 2:

TABLE 2
Texture coefficients of P—SiC according to example 1

| C₁₁₁ + C₂₂₂ + C₅₁₁ | C₂₂₀ | C₄₂₂ |
|---|---|---|
| 9% | 1% | 80% |

FIGS. 2 and 3 show a continuous increase in grain diameter over the first 200 microns. This increase in grain size can be evaluated for each ordinate of the reference frame by counting the number of intersections of a horizontal line of constant ordinate with the grain boundaries on the EBSD image.

The resulting layer contains a nitrogen concentration measured by SIMS of 8×10¹⁹ nitrogen atoms per cm³ and an electrical resistivity measured at 16 mohm·cm by the four-point method.

The thermal conductivity of the layer is deduced from the result of a thermal diffusivity measurement using the laser flash method. The value of 210 W/m/K was obtained.

Despite physical properties conforming to the intended objective, the deformation measured on the raw disk is much higher than the intended objective. Out of a total of 16 discs produced, the average deformation is 850 μm with a standard deviation of 140 μm. It will not be possible to produce a P-SiC wafer by rectification from a raw disk with a thickness of less than 1000 μm.

After several deposits under these conditions, the observed texturing is very preferentially oriented (422) with a texture coefficient C₄₂₂>75%.

### Example 2: Fine Grain Texture Oriented (111)

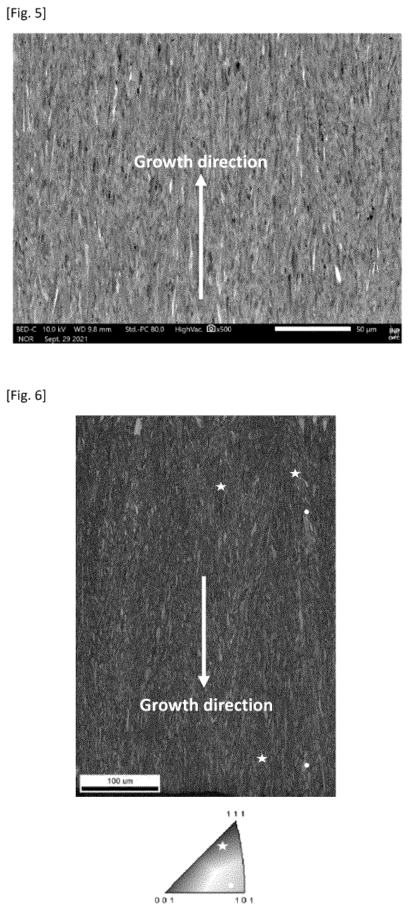

A 650 μm layer was deposited on a graphite substrate, operating at a temperature of 1550 K, a partial pressure of 8 mbar of MTCS and a molar fraction of NH₃ of 6%. FIGS. 4 and 5 are micrographs similar to FIGS. 2 and 3 of Example 1 (the white bar in FIG. 5 corresponds to a length of 50 μm).

The observed orientation is a preferentially oriented texturing (111) with texture coefficients collected in Table 3.

TABLE 3
Texture coefficients of P—SiC according to example 2

| C₁₁₁ + C₂₂₂ + C₅₁₁ | C₂₂₀ | C₄₂₂ |
|---|---|---|
| 86% | 1% | 8% |

FIG. 5 shows grains whose size does not increase as the growth of the P-SiC layer progresses; these are grains in the form of thin rods very oriented according to the normal to the plane of the substrate. The grain size can be evaluated for each ordinate of the reference frame by counting the number of intersections of a horizontal line of constant ordinate with the grain boundaries on the EBSD image.

The deposit obtained contains a nitrogen concentration measured by SIMS of 7×10²⁰ nitrogen atoms per cm³ and an electrical resistivity measured at 1.1 mOhm·cm by the 4-point method. The thermal conductivity of the layer is deduced by a measurement of thermal diffusivity using the laser flash method. The value of 52 W/m/K is obtained, which is well below the target. The fine-grained structure appears to strongly limit thermal conductivity.

The deformation measured on the raw disk is, on the other hand, very good. Out of a total of 16 discs produced, the average deformation is 190 μm with a standard deviation of 72 μm. This would allow the production by rectification of P-SiC wafers from a raw disk with a thickness of less than 1000 μm at a reasonable cost.

After several deposits under these conditions, the observed orientation is a very preferentially oriented texturing (111) with the sum of texture coefficient C₁₁₁+C₂₂₂+C₅₁₁>80%.

### Example 3: Fine Grain Texture Oriented (220)

A 650 μm layer was deposited on a graphite substrate, operating at a temperature of 1550 K, a partial pressure of 16 mbar of MTCS and a molar fraction of NH₃ of 4%.

FIGS. 6 and 7 are micrographs similar to FIGS. 2 and 3 of Example 1.

The observed orientation is a preferentially oriented texturing (220) with texture coefficients collected in Table 4:

TABLE 4
Texture coefficients of P—SiC according to example 3

| C₁₁₁ + C₂₂₂ + C₅₁₁ | C₂₂₀ | C₄₂₂ |
|---|---|---|
| 2% | 93% | 3% |

The deposit obtained contains a nitrogen concentration measured by SIMS of 1.8×10²⁰ nitrogen atoms per cm³ and an electrical resistivity measured at 5 mohm·cm by the 4-point method. The thermal conductivity of the layer is deduced by a measurement of thermal diffusivity using the laser flash method. The value of 270 W/m/K is obtained, which is above the target. Despite small grain sizes, the tree-like texture appears to promote good thermal conductivity, despite high doping.

The deformation measured on the raw disc is also very good. Out of a total of 16 discs produced, the average deformation is 210 μm with a standard deviation of 82 μm. This makes it possible to produce P-SiC wafers by rectification from a raw disc with a thickness of less than 1000 μm at a reasonable cost.

After several deposits under these conditions, the observed texture is very preferentially oriented (220) with the texture coefficient C₂₂₀>90% and C₄₂₂<10%

### Example 4: Fine Grain Texture Mainly Oriented (220) Mainly Mixed with Large Grains Oriented (422)

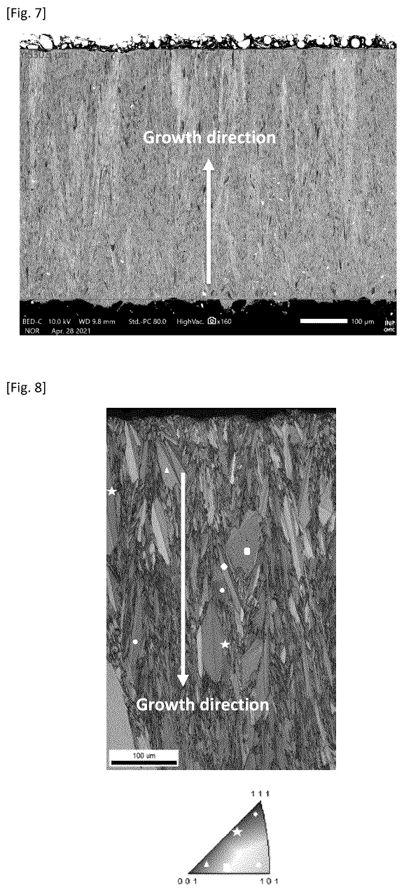

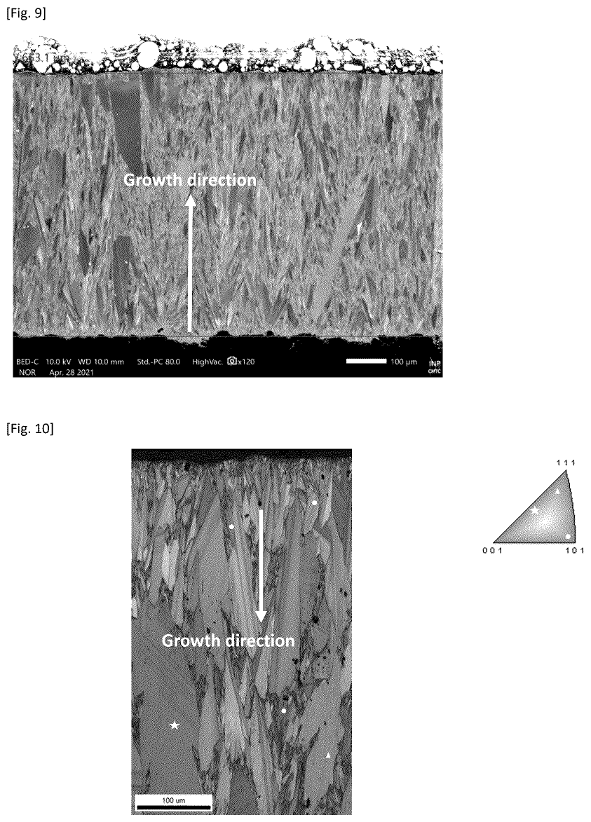

FIGS. 8 and 9 are micrographs similar to FIGS. 2 and 3 of Example 1.

An 800 μm layer was deposited on a graphite substrate, operating at a temperature of 1600 K, a partial pressure of 16 mbar of MTCS and a molar fraction of NH₃ of 4%. The observed texture was preferentially oriented (220) presenting large grains preferentially oriented (422) according to the texture coefficients gathered in table 5:

TABLE 5
Texture coefficients of P—SiC according to Example 4

| C₁₁₁ + C₂₂₂ + C₅₁₁ | C₂₂₀ | C₄₂₂ |
|---|---|---|
| 8% | 65% | 18% |

The figure shows two populations of grains of different dimensions. The (220) oriented grains have a diameter between 1 μm and 10 μm. The other grains, mainly oriented (422), have a conical shape whose diameter can increase up to 50 μm. The grain size can be evaluated for each ordinate of the reference frame by counting the number of intersections of a horizontal line of constant ordinate with the grain boundaries on the EBSD image. Here, the growth of the average grain size stabilizes quickly, because large grains remain a minority in the texture.

The deposit obtained contains a nitrogen concentration measured by SIMS of 2.2×10²⁰ nitrogen atoms per cm³ and an electrical resistivity measured at 3.3 mohm·cm by the 4-point method. The thermal conductivity of the layer is deduced by a measurement of thermal diffusivity using the laser flash method. A value of 215 W/m/K is obtained, which is above the target.

The deformation measured on the raw disc is also very good. Out of a total of 16 discs produced, the average deformation is 235 μm with a standard deviation of 90 μm. This makes it possible to produce P-SiC wafers by rectification from a raw disc with a thickness of less than 1000 μm at a reasonable cost.

After several deposits under these conditions, the observed texture remains preferentially oriented (220) with the texture coefficient C₂₂₀>60% and C₄₂₂<20%

### Example 5: Texture with Large Grains Oriented Mainly (422) Mainly Mixed with a Fine Texture of Small Grains Oriented (220)

An 800 μm layer was deposited on a graphite substrate, operating at a temperature of 1600 K, a partial pressure of 16 mbar of MTCS and a molar fraction of NH₃ of 6%.

FIGS. 10 and 11 are micrographs similar to FIGS. 2 and 3 of Example 1.

The observed texture is preferentially oriented (422), presenting very large grains oriented according to the texture coefficients collected in table 6:

TABLE 6
Texture coefficient of P—SiC according to example 5

| C₁₁₁ + C₂₂₂ + C₅₁₁ | C₂₂₀ | C₄₂₂ |
|---|---|---|
| 20% | 7% | 54% |

The figure shows very large grains oriented (422) predominantly or (111) in minority, which are conical in shape with diameters of up to 100 μm. A few small grains (220) smaller than 10 μm are very much in the minority. The figure shows a continuous growth in grain diameter over the first 500 microns. This growth in grain size can be evaluated for each ordinate of the reference frame by counting the number of intersections of a horizontal line of constant ordinate with the grain boundaries on the EBSD image.

The deposit obtained contains a nitrogen concentration measured by SIMS of 6.8 10²⁰ nitrogen atoms per cm³ and an electrical resistivity measured at 0.9 mohm·cm by the 4-point method, well below the targeted upper limit. The thermal conductivity of the layer is also deduced by a thermal diffusivity measurement using the laser flash method. A value of 130 W/m/K is obtained, which is below the target.

Out of a total of 16 discs produced, the average deformation is 650 μm with a standard deviation of 178 μm. It will not be possible to produce a P-SiC wafer by rectification from a raw disk with a thickness of less than 1000 μm.

After several deposits under these conditions, the observed texture remains preferentially oriented (422) with the texture coefficient C₄₂₂>50% and C₁₁₁+C₂₂₂+C₅₁₁>15% and C₂₂₀<10%.

### Example 6: Texture Obtained According to Example 3 but without the Addition of Dopant Gas

An 800 μm layer was deposited on a graphite substrate, operating under conditions almost identical to those of Example 3, i.e. at a temperature of 1550 K, a partial pressure of 16 mbar of MTCS, but with a molar fraction of NH₃ of 0%.

FIG. 13 is a micrograph analogous to FIG. 6 of Example 3.

The observed orientation is a texturing oriented mainly (422) then (111), with a (220) texture almost absent. The texture coefficients are collected in Table 7:

TABLE 7
Texture coefficients of P—SiC according to example 6

| C₁₁₁ + C₂₂₂ + C₅₁₁ | C₂₂₀ | C₄₂₂ |
|---|---|---|
| 30% | 3.5% | 40% |

The deposit obtained contains a nitrogen concentration below the SIMS detection threshold, much lower than 10¹⁹ nitrogen atoms per cm³, and an electrical resistivity of 56 ohm·cm, measured by the 4-point method. The thermal conductivity of the layer is deduced by a measurement of thermal diffusivity using the laser flash method. A value of 130 W/m/K is obtained, which is below the target.

The deformation measured on the raw disk does not conform to expectations. Out of a total of 16 discs produced, the average deformation is 530 μm with a standard deviation of 110 μm.

This will not allow the production by rectification of P-SiC wafers from a raw disk with a thickness of less than 1000 μm at a reasonable cost.

After several deposits under these conditions, the observed texture is mainly oriented (422) then (111) with the following texture coefficients: C₄₂₂>35% and C₁₁₁+C₂₂₂+C₅₁₁>20% and C₂₂₀<15%.

### Comparison of Examples 1 to 6

The main results obtained in relation to the examples presented above are gathered in Table 7 below:

TABLE 7
Main results of examples 1 to 6 above

| | | | | | | | N | Res | TC | |
|---|---|---|---|---|---|---|---|---|---|---|
| | Temp | MTCS | NH₃ | % | % C₁₁₁ + | % | [atm/ | [mOhm · | [W/ | Defor- |
| Ex | [K] | [mbar] | [%] | C₂₂₀ | C₂₂₂ + C₅₁₁ | C₄₂₂ | cm³] | cm] | m/K] | mation |
| 1 | 1550 | 23 | 3 | 1 | 9 | 80 | 8 × 10¹⁹ | 16 | 210 | NOK |
| 2 | 1550 | 8 | 6 | 1 | 86 | 8 | 7 × 10²⁰ | 1.1 | 52 | OK |
| 3 | 1550 | 16 | 4 | 93 | 2 | 3 | 1.8 × 10²⁰ | 5 | 270 | OK |
| 4 | 1600 | 16 | 4 | 65 | 8 | 18 | 2.2 × 10²⁰ | 3.3 | 215 | OK |
| 5 | 1600 | 16 | 6 | 7 | 20 | 54 | 6.8 × 10²⁰ | 0.9 | 130 | NOK |
| 6 | 1550 | 16 | 0 | 3.5 | 30 | 40 | <10¹⁹ | 56000 | 150 | NOK |

OK means « in conformity with target », NOK means the opposite.

Examples 2, 3 and 4 show a texture very oriented along the 2 possible axes (111) and (220) (C₂₂₀>60% or C₁₁₁+C₂₂₂+C₅₁₁>80%) and a contribution of the C₄₂₂ orientation always less than 20%. It is made up of a succession of fine, elongated grains. The grain stabilizes in diameter at 10 μm maximum for a length which can reach up to 100 μm.

Example 6, manufactured under the conditions of example 3 but without the addition of dopant gas, has a strong C₄₂₂ orientation >20% and a significant deformation which will not allow a P-SiC wafer to be produced by grinding from a raw blank with a thickness of less than 1,000 μm.

### LIST OF REFERENCE NUMERALS

The following reference numbers are used in FIG. 12 and in the description:
1 Reactor according to the invention
2 Enclosure
3 Reaction space
4 Heating space
5 Exhaust space
6 Heating element
7 Graphite susceptor
8 Precursor gas inlet
9 Reaction gas outlet
10 Outlet tip
11 Injector
12 Graphite discs (substrates)

1-16. (canceled)

17. A doped polycrystalline SiC plate having a preferential crystalline orientation, wherein said doped polycrystalline SiC plate has a texture coefficient C₄₂₂ of less than 30% and a texture coefficient C₂₂₀ of greater than 60%.

18. The doped polycrystalline SiC plate of claim 17, wherein said texture coefficient C₂₂₀ is greater than 80%.

19. The doped polycrystalline SiC plate of claim 17, wherein its electrical resistivity is less than 20 mOhm·cm, preferably less than 15 mOhm·cm, and even more preferably less than 10 mOhm·cm.

20. The doped polycrystalline SiC plate of claim 17, wherein the doped polycrystalline SiC plate is doped with nitrogen with a nitrogen content, measured by secondary ion mass spectroscopy, greater than 1.5×10²⁰ atoms/cm³.

21. The doped polycrystalline SiC plate of claim 17, wherein the texture coefficient C₄₂₂ is less than 10%.

22. The doped polycrystalline SiC plate of claim 17, wherein the doped polycrystalline SiC plate:
is doped with nitrogen with a nitrogen content, measured by secondary ion mass spectroscopy, greater than 5×10¹⁹ atoms/cm³, and
has an electrical resistivity of less than 15 mOhm·cm.

23. The doped polycrystalline SiC plate of claim 17, wherein the doped polycrystalline SiC plate is a raw blank resulting from a vapor deposition process.

24. The doped polycrystalline SiC plate of claim 23, wherein the doped polycrystalline SiC plate is an intermediate blank for manufacture of a wafer obtained by grinding a raw blank.

25. The doped polycrystalline SiC plate of claim 24, wherein the doped polycrystalline SiC plate has a thickness of less than 550 μm.

26. The doped polycrystalline SiC plate of claim 24, wherein the doped polycrystalline SiC plate has a thickness of between 355 μm and 420 μm.

27. The doped polycrystalline SiC plate of claim 17, wherein the doped polycrystalline SiC plate has a diameter between 140 mm and 165 mm, a thickness between 350 μm and 450 μm, and a deformation characterized by a Warp less than 50 μm.

28. The doped polycrystalline SiC plate of claim 17, wherein the doped polycrystalline SiC plate has a diameter between 140 mm and 165 mm, a thickness of between 350 μm and 400 μm, and a deformation characterized by a Warp less than 30 μm.

29. The doped polycrystalline SiC plate of claim 17, wherein the doped polycrystalline SiC plate has a diameter between 185 mm and 210 mm, a thickness between 500 μm and 650 μm, and a deformation characterized by a Warp less than 70 μm.

30. The doped polycrystalline SiC plate of claim 17, wherein the doped polycrystalline SiC plate has a diameter between 185 mm and 210 mm, a thickness between 500 μm and 600 μm, and a deformation characterized by a Warp less than 40 μm.

31. The doped polycrystalline SiC plate of claim 17, wherein the doped polycrystalline SiC plate is obtained by a CVD process.

32. A doped polycrystalline SiC plate having a preferential crystalline orientation, said doped polycrystalline SiC plate having a texture coefficient C₄₂₂ of less than 30%, wherein a sum of texture coefficients C₁₁₁+C₂₂₂+C₅₁₁ is greater than 70%.

33. The doped polycrystalline SiC plate of claim 32, wherein said sum of texture coefficients C₁₁₁+C₂₂₂+C₅₁₁ is greater than 80%.

34. The doped polycrystalline SiC plate of claim 32, wherein the doped polycrystalline SiC plate has a diameter between 140 mm and 165 mm, a thickness between 350 μm and 450 μm, and a deformation characterized by a Warp less than 50 μm.

35. The doped polycrystalline SiC plate of claim 32, wherein the doped polycrystalline SiC plate:
is doped with nitrogen with a nitrogen content, measured by secondary ion mass spectroscopy, greater than 5×10¹⁹ atoms/cm³, and
has an electrical resistivity of less than 15 mOhm·cm.

36. The doped polycrystalline SiC plate of claim 32, wherein the doped polycrystalline SiC plate has a diameter between 185 mm and 210 mm, a thickness between 500 μm and 650 μm, and a deformation characterized by a Warp less than 70 μm.

37. The doped polycrystalline SiC plate of claim 32, wherein the doped polycrystalline SiC plate has a diameter between 185 mm and 210 mm, a thickness between 500 μm and 600 μm, and a deformation characterized by a Warp less than 50 μm.

38. The doped polycrystalline SiC plate of claim 32, wherein the doped polycrystalline SiC plate:
has a diameter between 140 mm and 165 mm, a thickness between 350 μm and 450 μm, and a deformation characterized by a Warp less than 50 μm, and
is doped with nitrogen with a nitrogen content, measured by secondary ion mass spectroscopy, greater than 5×10¹⁹ atoms/cm³, and
has an electrical resistivity of less than 15 mOhm·cm.

39. The doped polycrystalline SiC plate of claim 32, wherein the doped polycrystalline SiC plate:
has a diameter between 185 mm and 210 mm, a thickness between 500 μm and 650 μm, and a deformation characterized by a Warp less than 70 μm, and
is doped with nitrogen with a nitrogen content, measured by secondary ion mass spectroscopy, greater than 5×10¹⁹ atoms/cm³, and
has an electrical resistivity of less than 15 mOhm·cm.

40. A method for manufacturing the polycrystalline SiC plate of claim 17, the method comprising:
forming, via chemical vapor deposition, a layer of polycrystalline SiC on a graphite surface of a substrate, in which a gas mixture is introduced into a heated enclosure so as to create a gas phase that includes at least one gaseous precursor of silicon and/or carbon, at least one dopant gas comprising at least one nitrogen atom, and a carrier gas, wherein the gas mixture decomposes on the graphite surface to form the layer of polycrystalline SiC on the graphite surface, and
heating the heated enclosure at a temperature in the heated enclosure (2) is of between 1450 K and 1650 K with a total partial pressure of the at least one gaseous precursor is less than 300 mbar.

41. The method of claim 40, wherein the gas phase comprises trichloromethylsilane without other precursors of silicon and/or carbon.

42. The method of claim 40, wherein the at least one dopant gas is selected from the group formed by NH₃, N₂H₄, N₂, and H₂NCH₃.

43. A method for manufacturing the polycrystalline SiC plate of claim 32, the method comprising:
forming, via chemical vapor deposition, a layer of polycrystalline SiC on a graphite surface of a substrate, in which a gas mixture is introduced into a heated enclosure so as to create a gas phase that includes at least one gaseous precursor of silicon and/or carbon, at least one dopant gas comprising at least one nitrogen atom, and a carrier gas, wherein the gas mixture decomposes on the graphite surface to form the layer of polycrystalline SiC on the graphite surface, and
heating the heated enclosure at a temperature in the heated enclosure (2) is of between 1450 K and 1650 K with a total partial pressure of the at least one gaseous precursor is less than 300 mbar.

44. The method of claim 43, wherein the gas phase comprises trichloromethylsilane without other precursors of silicon and/or carbon.

45. The method of claim 43, wherein the at least one dopant gas is selected from the group formed by NH₃, N₂H₄, N₂, and H₂NCH₃.
